(19) United States
(12) Patent Application Publication
(10) Pub. No.: US 2014/0218060 A1
(43) Pub. Date: Aug. 7, 2014

(54) DEGRADATION DIAGNOSING CIRCUIT AND DEGRADATION DIAGNOSING METHOD

(71) Applicant: Eisuke Saneyoshi, Tokyo (JP)

(72) Inventor: Eisuke Saneyoshi, Tokyo (JP)

(73) Assignee: NEC CORPORATION, Tokyo (JP)

(21) Appl. No.: 14/240,024

(22) PCT Filed: Aug. 15, 2012
(86) PCT No.: PCT/JP2012/071109

§ 371 Date: Feb. 20, 2014

(30) Foreign Application Priority Data
Aug. 24, 2011 (JP) 2011-182439

(51) Int. Cl. G01R 31/28

(52) U.S. Cl. CPC G01R 31/2884
USPC 324/750.3; 324/762.01

(57) ABSTRACT

In order to measure a state of degradation of a semiconductor integrated circuit more correctly by use of a simple configuration, a degradation diagnosing circuit includes: a test block including a first circuit which is an object of a degradation diagnosis; a reference block including a second circuit which has a configuration identical with a configuration of the first circuit; a judgment unit that judges whether a component of the test block is degraded or not by comparing a characteristic of a first signal outputted from the test block, and a characteristic of a second signal outputted from the reference block, in the case in which a signal indicating a measurement mode is inputted; and a control unit that outputs the signal which indicates the measurement mode to the judgment unit.

### TECHNICAL FIELD

The present invention relates to a degradation diagnosing circuit and a degradation diagnosing method for a semiconductor integrated circuit.

### BACKGROUND ART

Characteristics of a semiconductor integrated circuit become degraded due to usage after manufacture, an environmental condition or the like. In the case in which the degradation of the semiconductor integrated circuit progresses worse than a predetermined level, it is judged that the semiconductor integrated circuit is a defective product. However, in the case in which it is judged that the semiconductor integrated circuit is a defective product, it is generally difficult to judge whether a cause of having the bad quality is due to a life span (that is, proper degradation due to aging process), an incidental fault or the like.

Accordingly, in order to specify a true cause of the semiconductor integrated circuit's having the bad quality, it is very important to know a degree of progression of the degradation of the semiconductor integrated circuit after shipment. By knowing the degree of progression of the degradation of the semiconductor integrated circuit, it is possible to feed back the degree of progression of the degradation caused in the case in which an unexpected fault or degradation worse than an expected value is observed to a design of the semiconductor integrated circuit with ease. Moreover, by acquiring and analyzing log information on the degree of progression of the degradation, and estimating a proper time to replace the semiconductor integrated circuit, the degree of progression can be used effectively in setting an optimum maintenance time of the semiconductor integrated circuit.

It is desirable that the information on the degree of progression of the degradation of the semiconductor integrated circuit is outputted to the outside with no use of an external measurement tool, and furthermore is stored in the outside. As a means to realize the above, an art to calculate the degree of progression of the degradation of the semiconductor integrated circuit by mounting a ring oscillator on the semiconductor integrated circuit and measuring a change in an oscillation frequency of the ring oscillator is known.

Non-patent document 1 discloses a configuration which improves resolution of a degree of degradation in a practical area and makes a period of time for measurement short by using two CMOS (Complementary Metal Oxide Semiconductor) ring oscillators. Specifically, non-patent document 1 describes a configuration which measures a ratio of the oscillation frequencies of two ring oscillators.

Patent document 1 discloses a configuration for measuring degradation of MOSFET (Metal-Oxide-Semiconductor Field-Effect Transistor) by using two CMOS ring oscillators. A semiconductor integrated circuit described in the patent document 1 includes two ring oscillators. When measuring the degradation, a part of one circuit branches, and connection is set up so that the part of one circuit may be replaced with a part of the other circuit. Then, by comparing phases of output signals of one circuit and the other circuit, a change in an amount of signal delay due to characteristics degradation of the circuit is detected.

Patent document 2 discloses a configuration which judges whether a circuit is broken or not on the basis of a judgment whether a signal propagation delay of a circuit which is a degradation diagnosis object is shorter than a reference value or not. According to a degradation diagnosing circuit described in patent document 2, a degradation diagnosis of the circuit is carried out by using only the degradation diagnosing circuit.

Moreover, a patent document 3 discloses a configuration for detecting degradation due to the aging process of a signal delay path. According to a semiconductor integrated circuit described in a patent document 3, a result of comparing amounts of delay of delay paths different each other is stored in a memory before shipment, and it is judged that the delay path is caused a fault in the case in which, when the similar measurement is carried out after the shipment, the comparison result on largeness of the amount of delay after the shipment is different from the comparison result obtained before the shipment.

### PRIOR ART DOCUMENT

### Patent document

[Patent document 1] Japanese Patent Application Laid-Open No. 2010-087275
[Patent document 2] Japanese Patent Application Laid-Open No. 2008-147245
[Patent document 3] Japanese Patent Application Laid-Open No. 2010-287860

### Non-Patent Document

[Non-patent document 1] Tae-Hyoung Kim, Randy Persaud, and

Chris H. Kim, ‘Silicon Odometer: An On-Chip Reliability Monitor for Measuring Frequency Degradation of Digital Circuits’, IEEE JOURNAL OF SOLID-STATE CIRCUITS, VOL. 43, NO. 4, pp. 874-880, April, 2008

### DISCLOSURE OF THE INVENTION

### Technical Problems

The method which is described in the non-patent document 1 for judging the degree of progression of the degradation of the semiconductor integrated circuit by use of the change of the oscillation frequency of the ring oscillator has a problem that the measured oscillation frequency changes severely due to the influence of the environment. As the influence which the environment causes to the oscillation frequency, variation in chip temperature and variation in a power supply voltage of the semiconductor integrated circuit are exemplified. According to the non-patent document 1, the influence due to the environment is reduced to some extent by measuring the ratio of the oscillation frequencies of two ring oscillators. However, according to the configuration described in the non-patent document 1, the signal which indicates difference between the frequencies of two ring oscillations is generated in order to measure the change of the oscillation frequency. For this reason, the configuration of the non-patent document 1 has a problem that a circuit configuration becomes complicated.

Moreover, the semiconductor integrated circuit described in the patent document 1 compares the delays by use of only a part of one circuit and a part of the other circuit. For this reason, the configuration described in the patent document 1 has a problem that it is impossible to find out a correct amount of characteristics degradation which should be based on an amount of delay degradation of the whole ring oscillator.

Furthermore, since the degradation diagnosing circuit described in the patent document 2 carries out the degradation diagnosis without using a signal of the real circuit, there is fear that a result of the degradation diagnosis does not match with a state of the real circuit. Additionally, the degradation diagnosing circuit described in the patent document 2 has another problem that it is necessary to generate the accurate reference signal and to carry out complicated setting for diagnosing the degradation.

Furthermore, according to the semiconductor integrated circuit apparatus described in the patent document 3, it is necessary to measure the delay value before the shipment and to store the delay value in the non-volatile memory. For this reason, the semiconductor integrated circuit apparatus described in the patent document 3 has a problem that a cost rises by use of an expensive device such as a memory and by increase of number of procedures for manufacturing.

An object of the present invention is to provide an art which solves a problem to measure a state of the degradation of the semiconductor integrated circuit more correctly by use of a simple configuration.

### Technical Solution

A degradation diagnosing circuit according to the present invention includes: a test block including a first circuit which is an object of a degradation diagnosis; a reference block including a second circuit which has a configuration identical with a configuration of the first circuit; a judgment means for judging whether a component of the test block is degraded or not by comparing characteristics of a first signal outputted from the test block and characteristics of a second signal outputted from the reference block, in the case in which a signal indicating a measurement mode is inputted; and a control means for outputting the signal which indicates the measurement mode to the judgment means.

A degradation diagnosing method according to the present invention judges whether a component of a test block, which includes a first circuit which is an object of a degradation diagnosis, is degraded or not by comparing characteristics of a first signal outputted from the test block and characteristics of a second signal outputted from a reference block including a second circuit, which has a configuration identical with a configuration of the first circuit, in the case in which a signal indicating a measurement mode is inputted.

### Effect of the Invention

The present invention makes it possible to measure a state of the degradation of the semiconductor integrated circuit more correctly by use of a simple configuration.

### BRIEF DESCRIPTION OF THE DRAWINGS

FIG. 1A diagram showing a configuration of a degradation diagnosing circuit according to a first exemplary embodiment

FIG. 2 A diagram showing a configuration of a modification of the degradation diagnosing circuit according to the first exemplary embodiment

FIG. 3 A diagram showing a configuration of a degradation diagnosing circuit according to a second exemplary embodiment

FIG. 4 A diagram showing a configuration of a degradation diagnosing circuit according to a third exemplary embodiment

FIG. 5 A diagram showing logic of input/output signals of DFF, and logic of an output signal of EX-OR in the second exemplary embodiment.

### EXEMPLARY EMBODIMENT TO CARRY OUT THE INVENTION

Next, an exemplary embodiment according to the present invention will be described with referring the drawings.

### First Exemplary Embodiment

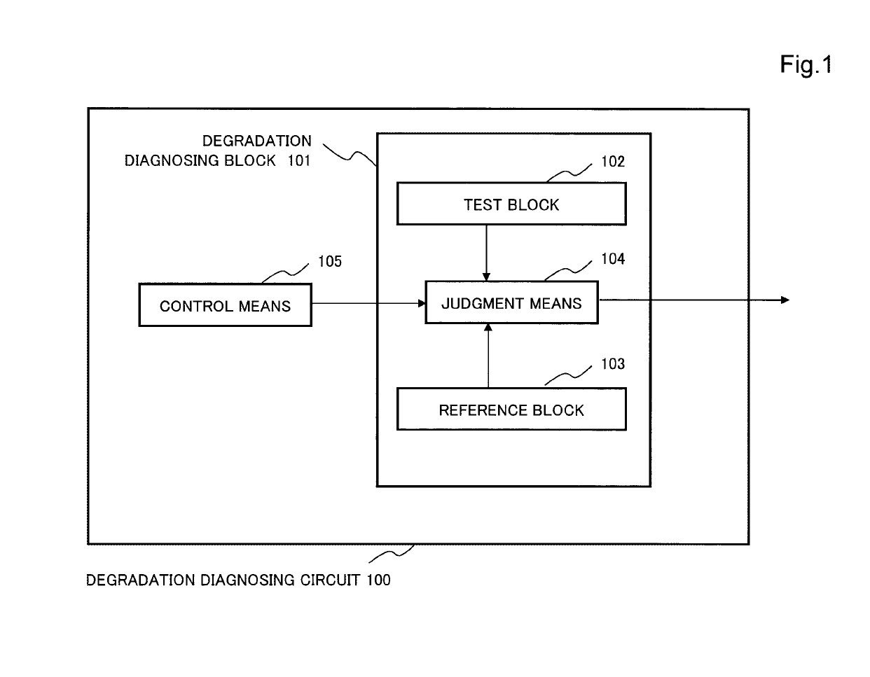

FIG. 1 is a diagram showing a configuration of a degradation diagnosing circuit according to a first exemplary embodiment.

As shown in FIG. 1, a degradation diagnosing circuit 100 includes a degradation diagnosing block 101 and a control means 105. Moreover, the degradation diagnosing block 101 includes a test block 102, a reference block 103 and a judgment means 104.

When a semiconductor integrated circuit included in a circuit of the test block is caused degradation as a result of applying a stress to the test block 102, there is a case in which a delay which is one kind of characteristics of a logic gate of the semiconductor integrated circuit may be increasing. As will be mentioned later, amounts of stresses applied to the test block 102 and the reference block 103 are set to be different each other. An amount of the stress means, for example, strength of the stress or a length of a time when the stress is applied. Therefore, a difference in largeness of the degradation (degree of degradation) between the test block 102 and the reference block 103 is caused. Accordingly, due to the degradation of the semiconductor integrated circuit of the test block 102, the logic gate of the test block 102 is caused the delay more severely than one of the reference block 103. As a result, an output signal of the test block 102 is caused the delay gradually in comparison with an output signal of the reference block 103. The judgment means 104 judges a state of the degradation of the test block 102 on the basis of the detecting the delay.

The judgment means 104 has two operation states of a stand-by mode and a measurement mode. The stand-by mode means a state in which the degradation diagnosing block 101 does not carry out the measurement of the degradation of the test block 102. The measurement mode means a state in which the degradation diagnosing block 101 carries out the measurement of the degradation of the test block 102.

The test block includes a first circuit which is an object of a degradation diagnosis. The reference block includes a second circuit which has a configuration identical with a configuration of the first circuit. The test block 102 and the reference block 103 output a first signal and a second signal respectively to the judgment means 104. The control means 105 outputs a signal which indicates the stand-by mode or the measurement mode to the judgment means 104.

In the case in which the signal inputted from the control means 105 indicates the measurement mode, the judgment means 104 carries out the following operation. That is, in the measurement mode, the judgment means 104 compares the first signal inputted from the block test 102, and the second signal inputted from the reference block 103, and judges whether a component of the test block 102 is degraded or not.

It is possible to apply stresses which progress the degradation of the semiconductor integrated circuits to the test block 102 and the reference block 103. It is possible to apply the stress by applying a power supply voltage or not, changing a power supply voltage, changing a surrounding temperature, changing an operation frequency, changing a load of the circuit, and the like. However, a kind of the stress is not limited to the above. If a stress other than the above is a cause which influences life span of the semiconductor integrated circuit, the stress may be applied to either of or both of the test block 102 and the reference block 103.

Moreover, a plurality of kinds of stresses may be applied to the test block 102 and the reference block 103 simultaneously. At this time, it is desirable that a kind and strength of the stress applied to the test block 102 are different from ones applied to the reference block 103.

For example, in the stand-by mode, by applying the stress to the test block 102, the test block 102 may be set to be in a state in which the degradation is progressed, and simultaneously by connecting a power supply terminal of the semiconductor integrated circuit of the reference block 103 with the ground potential, the reference block 103 may be set to be in a state in which any stress is not applied, that is, in a state in which the degradation is not progressed. Or, stresses may be applied to both of the test block 102 and the reference block 103 also in the stand-by mode, and furthermore a difference in an operation condition such as temperature and an operation frequency between the stresses may be set. Here, positions of the test block 102 and the reference block 103 may be switched each other.

On the other hand, in the measurement mode, the judgment means 104 compares timing of two signals, that is, the output signal of the test block 102 and the output signal of the reference block 103, and finds out a difference in the timing.

As a specific configuration, each of the test block 102 and the reference block 103 may include an oscillation circuit and may output an output signal of the oscillation circuit to the judgment means 104.

The judgment means 104 compares characteristics of the signals outputted by the test block 102 and the reference block 103, and judges a state of the degradation of the test block 102. In the case in which the test block 102 and the reference block 103 include the oscillation circuits, an oscillation frequency and a signal phase are used as the characteristics of the signal.

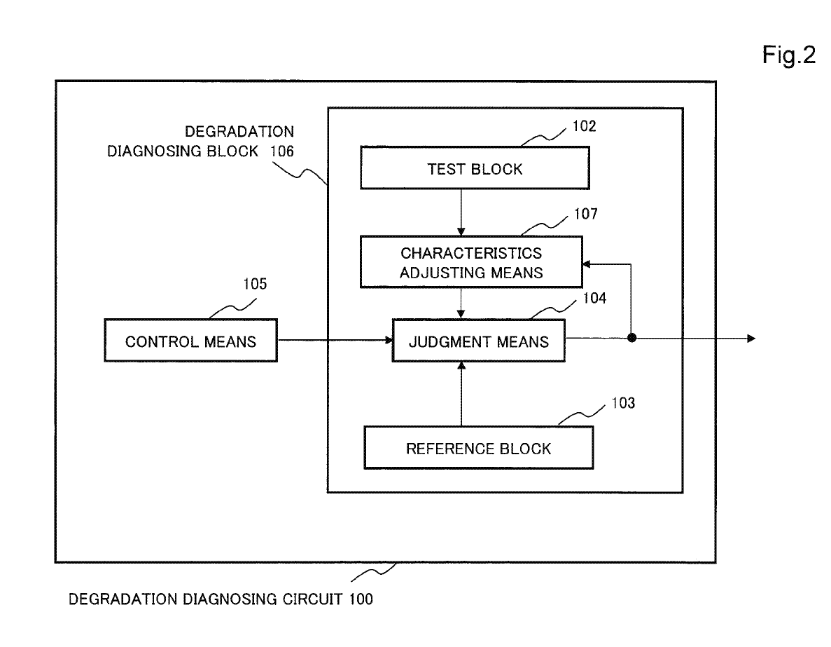

FIG. 2 is a diagram showing a configuration of a modification of the degradation diagnosing circuit according to the first exemplary embodiment. A degradation diagnosing block 106 shown in FIG. 2 includes a characteristics adjusting means 107 arranged between the test block 102 and the judgment means 104. The characteristics adjusting means 107 adjusts the characteristics of the signal outputted by the test block 102 and makes the adjusted characteristics inputted to the judgment means 104. An output of the judgment means 104 is inputted to the characteristics adjusting means 107. The characteristics adjusting means 107 adjusts the characteristics (for example, delay time) of the output of the test block 102 so that a difference in the characteristics between the test block 102 and the reference block 102 may not be detected at an output point of the judgment means 104. Here, the judgment means 104 may have a function to direct the characteristics adjusting means 107 to adjust or not to adjust the characteristics of the signal inputted to the characteristics adjusting means 107. According to the modification of the first exemplary embodiment shown in FIG. 2, amounts of adjustment of the characteristics which the characteristics adjusting means 107 carries out can be defined as an amount of the degradation of the test block 102.

Incidentally, the characteristics adjusting means 107 may be arranged between the reference block 103 and the judgment means 104. Also in this case, an amount of the adjustment of the characteristics which the characteristics adjusting means 107 carries out in the state in which the difference in the characteristics between the test block 102 and the reference block 103 is not detected at the output point of the judgment means 104 can be defined as an amount of the degradation of the test block 102. Furthermore, the characteristics adjusting means 107 may be arranged between the test block 102 and the judgment means 104, and between the reference block 103 and the judgment means 104. In this case, a difference between amounts of the adjustment of the characteristics carried out by two characteristics adjusting means 107, in the state in which the difference in the characteristics between the test block 102 and the reference block 103 is not detected at the output point of the judgment means 104 can be defined as an amount of the degradation of the test block 102. Furthermore, in the modification of the first exemplary embodiment, the degradation diagnosing block 106 may have a function to output an amount of the adjustment of the characteristics which the characteristics adjusting means 107 carries out, to the outside.

Here, in the degradation diagnosing block 106, the judgment means 104 may judge that the test block 102 is not degraded in the case in which the characteristics of the test block 102 and the characteristics of the reference block 103 are identical each other without adjusting the signal characteristics by the characteristics adjusting means 107. In this case, it is unnecessary that the judgment means 104 directs the characteristics adjusting means 107 to adjust the signal characteristics. Accordingly, on the basis of the unnecessariness to direct the characteristics adjusting means 107 to adjust the signal characteristics, the judgment means 104 may judge that the test block 102 is not degraded.

Incidentally, in the case in which the degradation diagnosing circuit is in the stand-by mode, operation states of the test block and the reference block can be set optionally. For example, also in the stand-by mode, the test block may operate, and the reference block may stop the operation.

The above-mentioned ‘characteristics’ are the predetermined electrical characteristics which the signals outputted by the test block 102 and the reference block 103 have and which can be observed, and any characteristics are applicable to ‘characteristics’ if the characteristics can be used for the degradation diagnosis of the semiconductor integrated circuit. Accordingly, ‘characteristics’ include a phase, timing of a change, and a frequency which are related to a temporal aspect of the signal, and include an output voltage, an output current, a voltage amplitude, a current amplitude, and an ability to drive a load which are related to a largeness aspect of the signal.

According to the exemplary embodiment, by detecting the above-mentioned difference in ‘characteristics’, a diagnosis that the degradation is caused is made. Therefore, a specific method of detecting the difference in the characteristics is not limited. For example, the judgment means 104 may be equipped with a phase comparator in order to detect a difference in the signal phase, the timing of the change, or the frequency of the signal. The judgment means 104 may be equipped with a voltage comparator in order to detect the difference in the voltage of the signal. Moreover, for example, a difference in the electric current of the signal between the test block 102 and the reference block 103 may be found out on the basis of a difference in a voltage which each signal generates at a resistor. Moreover, in the case in which the signal is connected with a predetermined load, the ability to drive the load may be found out on the basis of a variation of a voltage or a current which are caused the signal.

According to the first exemplary embodiment described above, a state of the degradation of the semiconductor integrated circuit is measured by use of the easy configuration. Then, even if an environmental variation (for example, variation of a power supply voltage or surrounding temperature) is caused at a time of the measurement, by controlling the measurement of the degradation diagnosing block which includes two blocks, the difference in the delay time is calculated after an environmental variation equivalent to the caused environmental variation is added to the test block 102 and the reference block 103. As a result, it is possible to offset the influence of the environmental variation.

Moreover, a phenomenon, called BTI (Bias Temperature Instability), that a state of degradation of a circuit component is restored when a stress which has been added to the circuit element is removed is known. There is fear that a state of the degradation is misjudged due to BTI if the stress applied to the circuit component in the measurement mode is different from the stress applied to the circuit component in the stand-by mode. According to the degradation diagnosing circuit of the first exemplary embodiment, the judgment means 104 judges a state of the degradation in the measurement mode on the basis of the signals outputted by the test block 102 and the reference block 103. As mentioned above, the test block 102 may operate also in the stand-by mode in which the control means 105 does not output the signal indicating the measurement mode. In the stand-by mode, the reference block 103 may stop the operation. By virtue of the operation mentioned above, the degradation diagnosing circuit 100 according to the first exemplary embodiment can transit from the stand-by state to the measurement state successively with maintaining the state in which the stress is applied to the test block 102. For this reason, the degradation diagnosing circuit according to the first exemplary embodiment has an effect that it is possible to reduce the influence of the degradation of recovery due to the influence of BTI.

### Second Exemplary Embodiment

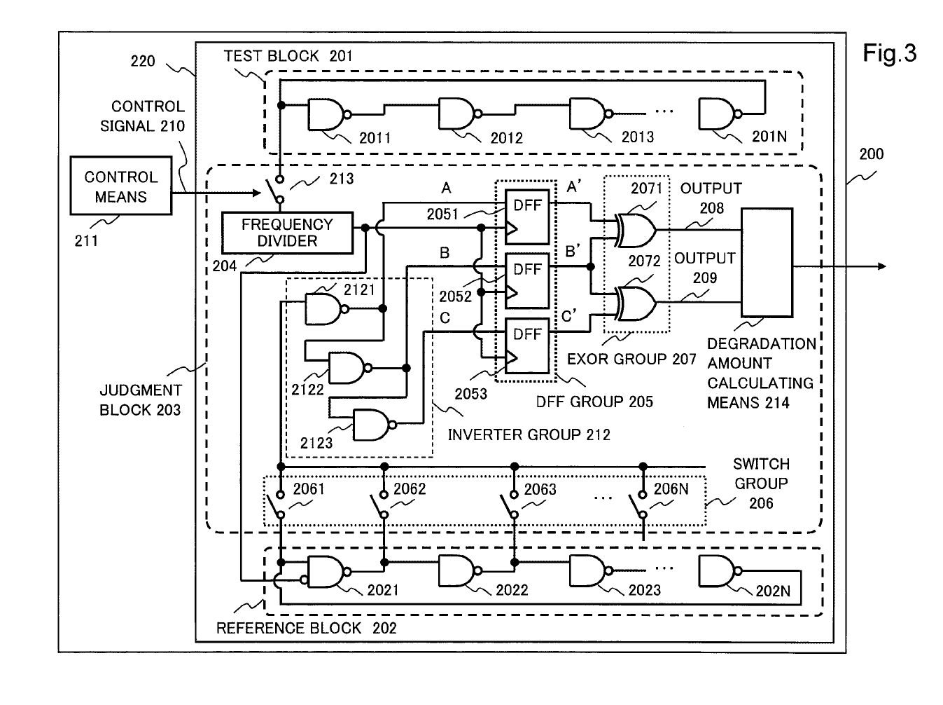

FIG. 3 is a diagram showing a configuration of a degradation diagnosing circuit according to a second exemplary embodiment. A degradation diagnosing circuit 200 shown in FIG. 3 includes a degradation diagnosing block 220 and a control means 211. The degradation diagnosing block 220 includes a test block 201, a reference block 202, and a judgment means 203. Here, components, description and the like, which are unnecessary to describe an operation, are omitted appropriately, and a configuration shown in FIG. 3 is not limited as only one configuration which can achieve the object of the present invention.

The test block 201 and the reference block 202 shown in FIG. 3 include logic gates. According to the second exemplary embodiment, the test block 201 has a configuration of a ring oscillator which includes N NAND (Not AND) gates 2011, 2012, . . . , 201N which outputs cycle like on a loop. Electric potential of an input terminal which each of the NAND gates 2011, 2012, . . . , 201N has and is not shown in the figure, is fixed to a ‘H’ level. Accordingly, the NAND gates 2011, 2012, . . . , 201N operate as an inverter. However, a NOR (Not OR) gate and other kinds of logic gates may be used as the logic gate. As far as an oscillation condition of the ring oscillator is satisfied, number of stages of the logic gates has no limitation in particular. However, it is possible to make the degradation diagnosing circuit small-sized as the number of stages of the logic gates becomes small.

Similarly to the test block 201, the reference block 202 is equipped with a ring oscillator including N NAND gates 2021, 2022, . . . , 202N. Here, an output of a frequency divider 204 is inverted, and the inverted output is inputted to an input terminal which the NAND gate 2021 has and is not included in the loop. Moreover, electric potential of an input terminal which each of the NAND gates 2022, . . . , 202N has and is not shown in the figure, is fixed to the ‘H’ level. Accordingly, the NAND gates 2022, . . . , 202N operate as an inverter.

The judgment means 203 includes the frequency divider 204, a DFF (D-flip flop) group 205, a switch group 206, an EXOR (exclusive-OR) group 207, an inverter group 212 and a degradation amount calculating means 214.

The frequency divider 204 divides a frequency of a signal inputted from any one of branch points (hereinafter, referred to as ‘node’) each of which is arranged between the logic gates of the test block 201, and outputs a signal which has the divided frequency to the DFF group 205 and the NAND gate 2021 of the reference block 202.

The switch group 206 includes N switches 2061, 2062, . . . , 206N and makes an output of one node selected out of the nodes of the reference block 202 inputted to the inverter group 212. That is, only one out of the switches 2061 to 206N is in an ON (short) state simultaneously.

The inverter group 212 includes three NAND gates 2121 to 2123 connected in series. Electric potential of an input terminal which each of the NAND gates 2121 to 2123 has and is not shown in the figure is fixed to the ‘H’ level. Accordingly, the NAND gates 2121 to 2123 operate as an inverter respectively. The inverter group 212 inverts the signal provided by the node, which the switch group 206 has been selected, every time when the signal passes the NAND gates 2121 to 2123. Then, outputs of the NAND gates 2121 to 2123 are inputted to the DFF group 205.

The DFF group 205 includes DFFs 2051 to 2053. DFFs 2051 to 2053 hold the signals inputted from the NAND gates 2121 to 2123 respectively at a rising edge of the output of the frequency divider 204. The EXOR group 207 includes EXOR gates 2071 and 2072. The EXOR gate 2071 carries out the exclusive-or operation to outputs of DFFs 2051 and 2052, and outputs the operation result to the degradation amount calculating means 214 as an output 208. The EXOR gate 2072 carries out the exclusive-or operation to outputs of DFFs 2052 and 2053, and outputs the operation result to the degradation amount calculating means 214 as an output 209.

The degradation amount calculating means 214 calculates an amount of degradation of the test block 201 on the basis of the outputs 208 and 209. A specific method of the degradation amount calculating means 214 calculating an amount of the degradation will be described later.

Connecting and disconnecting the node of the test block 201 and the frequency divider 204 are carried out by a switch 213. The switch 213 is controlled by a control signal 210 outputted by the control means 211. The connection and disconnection between the node of the test block 201 and the frequency divider 204 can be set up by the control signal 210.

In the second exemplary embodiment, a state in which a situation of the degradation is not measured is called a stand-by mode, and a state in which a situation of the degradation is measured is called a measurement mode. An operation in the stand-by mode and the measurement mode will be described in the following. It is clear that an operation described in the following is a mere example and is not only one operation that can achieve the object of the present invention.

In the stand-by mode, the control means 211 outputs the control signal 210 so that the switch 213 may disconnect the test block 201 and the frequency divider 204. Then, the test block 201 carries out self-oscillation as the ring oscillator. Here, the test block 201 may be configured so that an external control signal not shown in the figure may control an operational condition of the ring oscillator. An operation of the reference block 202 is also similar to that of the test block 201. By a difference between the stresses (such as voltage and temperature) applied to the test block 201 and the reference block 202, it becomes possible to evaluate a situation of the degradation of the test block 201 under the condition of the different stresses.

In the measurement mode, a specific node of the test block 201 and the frequency divider 204 are connected each other by the control signal 210. Transition from the stand-by mode to the measurement mode is carried out by outputting the control signal 210 so that the control means 211 may turn on the switch 213. That is, a different point between the circuit configuration in the stand-by mode and the circuit configuration in the measurement mode is that the switch 213 is OFF or ON. Accordingly, in the case of the degradation diagnosing circuit 200, it is possible to transit from the stand-by mode to the measurement mode without changing the circuit configuration of each block while applying the stresses to the test block 201 and the reference block 202.

In the measurement mode, the signal of the node of the test block 201 is inputted to the frequency divider 204. The frequency divider 204 divides a frequency of the signal inputted from the test block 201 in a predetermined frequency division ratio. As a result, the output of the frequency divider 204 has an ‘H’ level and an ‘L’ level alternately in a cycle which accords with the frequency division ratio. For example, in the case in which the output signal level of the frequency divider 204 is ‘H’ just before entering into the measurement mode, the output of the frequency divider 204 changes hereinafter in an order of ‘L’ and ‘H’.

First, an operation carried out when the output of the frequency divider 204 changes to ‘L’, will be described. The output of the frequency divider 204 is inverted, and the inverted output is inputted to an input terminal of the NAND gate 2021. Accordingly, in the case in which the output signal of the frequency divider 204 is ‘H’, an output of the NAND gate 2021 is fixed to ‘H’. When the output signal of the frequency divider 204 is changed to ‘L’, the reference block 202 starts oscillating. Only one switch out of the switches 2061 to 206N is selected at the same time. The selection procedure will be described later.

Next, when signals of which number is corresponding to the frequency division ratio are inputted from the test block 201, the output of the frequency divider 204 is changed to ‘H’. At this time, outputs of DFF group 205 hold the output level of the node selected in the reference block 202. A logical operation is carried out to the output level hold by the DFF group 205 by the EXOR group 207 arranged at the rear of the DFF group 205, and then result of the logical operation are outputted as the output 208 and the output 209.

Incidentally, the reference block 202 stops the oscillation operation by the change of the output of the frequency divider 204 from ‘L’ to ‘H’. Since the reference block 202 stopping the oscillation operation, and the DFF group 205 latching the input data provided by the switch group 206 are carried out simultaneously, there is fear that the output signals of the DFF group 205 may be caused disorder. A delay circuit may be arranged between the frequency divider 204 and the reference block 202 so that the DFF group 205 may latch the input signal correctly at a time when the output of the frequency divider 204 changes. Or, a hold circuit may be arranged so that the hold circuit holds the signal with which the frequency divider 204 provides the reference block 202 until the DFF group 205 latches the input signal. Or, starting and stopping the oscillation of the reference block 202 may be controlled by using the control signal 210 instead of using the output of the frequency divider 204.

Hereinafter, a method used by the degradation amount calculating means 214 calculating a state of the degradation will be described. To make the description simple, it is assumed in the following description that only the test block 201 is degraded. However, also in the case in which an operational environment of at least one of the test block 201 and the reference block 202 is changed, it is understood easily that a state of the degradation can be calculated relatively. Furthermore, also in the case in which the test block 201 and the reference block 202 are swapped each other, etc., a state of the degradation can be calculated relatively.

The connection between the test block 201 and the frequency divider 204 is described on the basis of the configuration shown in FIG. 3 whose explanation is easy. However, also in the case in which a ring oscillator with another configuration, or another circuit capable of timing comparison with the reference block 202 is used, it is possible to measure an amount of the delay of the signal outputted by the test block, and to find out an amount of the degradation of the test block by carrying out the similar operation.

In a degradation detecting circuit 220 shown in FIG. 3, an interval between change points of the output of the frequency divider 204 in the case in which the test block 201 and the frequency divider 204 are used is expressed by the following formula (1).

(T+ΔT)×2×N×M (1)

Here, T is an amount of delay per one NAND gate of the test block 201, and ΔT is an increasing amount of delay due to the degradation per one NAND gate of the test block 201. Moreover, N is the number of the NAND gates of the test block 201, and M is the frequency division ratio of the frequency divider 204. That is, a value calculated by the formula (1) is a total of amounts of the delay caused in the test block at the interval between the change points of the output of the frequency divider 204. Here, since internal circuits of the NAND gates 2011 to 201N are identical each other, it is assumed that increasing amounts of the delay caused to the NAND gates 2011 to 201N at a time of performance degradation are identical each other.

On the other hand, an amount of the delay of the reference block 202 is expressed similarly by the following formula (2).

T×X (2)

The formula (2) indicates an amount of the delay outputted by the reference block 202 at the interval between the change points of the output of the frequency divider 204.

Here, X is a total number of the NAND gates through which the signal passes in the block reference 202 from a falling edge up to a rising edge of the output of the frequency divider 204. In order to measure X, it is necessary in general to arrange a counter and many DFFs also in the reference block 202. Then, according to the second exemplary embodiment, in order to make the degradation detecting circuit simplified and small-sized, a difference in an amount of the delay between the test block 201 and the reference block 202 is measured without finding out X directly by use of the counter or the like. For this reason, the degradation detecting circuit 220 selects a node of the reference block 202 whose signal is inputted to the DFF group at a start time of the measurement mode. A specific procedure will be described in the following.

First, the switch group 206 selects one node before a rising edge of an output of the frequency divider 204. Then, a node which makes a level of the output 208 and a level of the output 209 not coincident at a falling edge of time of the output of the frequency divider 204 is searched. That is, a node which makes the output 208 and the output 209 ‘L’ and ‘H’ or makes the output 208 and the output 209 ‘H’ and ‘L’ is searched. Here, ON and OFF control of the switch group 206 and the level check of the outputs 208 and 209 may be carried out by the judgment means 203 or by other equipment which controls the judgment means 203 by remote control.

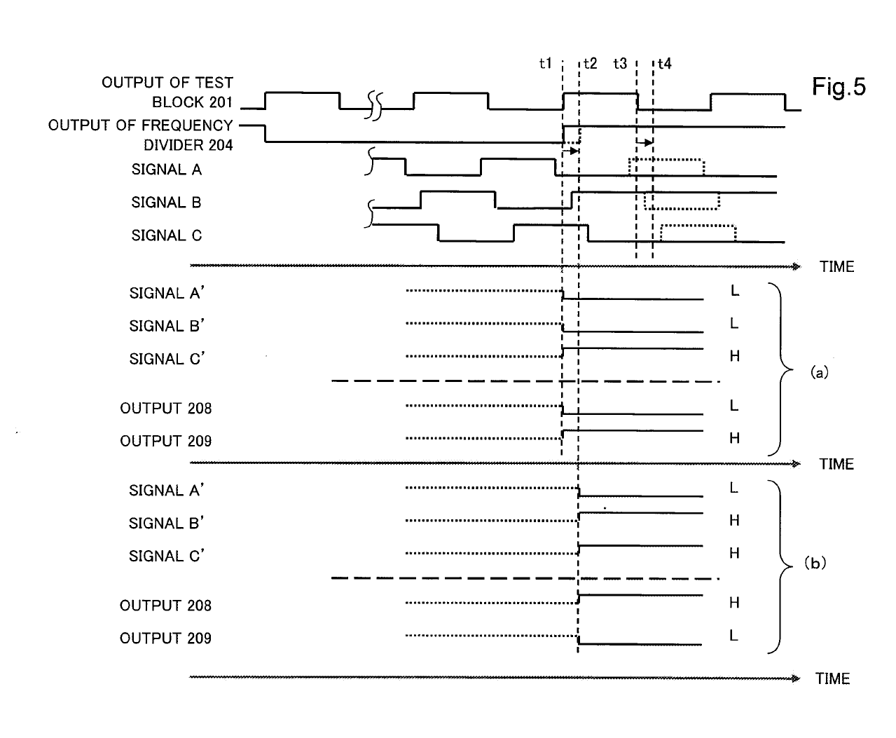

FIG. 5 is a diagram showing signal timing in the second exemplary embodiment. In FIG. 5, the output of the frequency divider 204 is the signal whose frequency is the divided frequency of the output of the test block 201. Signals A to C and signals A′ to C′ indicate inputs and outputs of DFFs 2051 to 2053 respectively. FIG. 5 is a timing chart showing a case in which, at a time of starting the measurement mode, any one of the switches 2061 to 206N which makes the output 208 and the output 209 ‘L’ and ‘H’ respectively is selected and turned on.

The circuit configurations of the test block 201 and the reference block 202 as the ring oscillator are the same each other. Accordingly, in the case in which the test block 201 is not degraded in comparison with the reference block 202, a timing relation between the output of the frequency divider 201 and the signals with which the reference block provides the DFF group (A to C), is not changed ((a) in FIG. 5). However, when the degradation of the test block 201 progresses and consequently the delay of the output of the test block 202 increases, rising edge of the output of the frequency divider 204 becomes delayed in comparison with the input signals of the DFF group (A to C). When the degradation of the test block 201 progresses and consequently the rising edge of the output of the frequency divider 204 is delayed from t1 up to t2 shown in FIG. 5, the output signal ‘B’ of the DFF 2052 is inverted. As a result, both of the outputs 208 and 209 are inverted, that is, the output 208 becomes ‘H’, and the output 209 becomes ‘L’ ((b) in FIG. 5).

Since the NAND gates 2121 to 2123 are connected in series, timing of the input signals A to C of the DFF group 205 is delayed in an order of A, B and C, and a delay between A and B, and a delay between B and C are corresponding to a delay of one NAND gate of the inverter group 212. In the case in which the rising edge of the output of the frequency divider 204 is delayed from t1 up to t2 with interposing a time of inverting the output signal ‘B” of DFF 2052, an amount of the delay between the rising edge and the falling edge of the output of the frequency divider 204 is corresponding to the delay of one NAND gate on the average. It is conceivable that the delay corresponding to the delay of one gate increases due to the degradation. Here, number of the gates through which the signal passes in the test block 201 is ‘2×N×M’. For this reason, in the case that the signals A′ to C′ and the outputs 208 and 209 change from (a) to (b) shown in FIG. 5, the degradation amount calculating means 214 can calculate an amount of the degradation per one gate of the test block 201 to be 1/(2×N×M).

Incidentally, after both of the outputs 208 and output 209 are inverted, that is, the output 208 becomes ‘H’ and the output 209 is “L”, the judgment means 203 may select the node by use of the switch group 206 again. For example, the judgment means 203 may shift the node to be selected in the reference block 202 to just rear of the previous node, in the state in which the rising edge of the output of the frequency divider 204 is delayed up to t2 shown in FIG. 5. In the case in which the node is shifted to just rear of the previous node is selected, the signals A to C in this case are indicated by a dotted line in FIG. 5. With respect to a relation among the signals shown by the dotted line in FIG. 5, the signal B is changed as to be a new signal A, and a new signal B and a new signal C are changed as to be inversions of the new signal A and the new signal B respectively. As a result, by shifting the node to the just rear of the previous node, the relations between the rising edge of the output of the frequency divider 204 and the input signals A to C of the DFF group 205 are similar to ones at t1 shown in FIG. 5.

As mentioned above, it is possible to make the output 208 and the output 209 enter into the states of ‘L’ and ‘H’ respectively by the switch group 206 shifting the node to just rear of the previous node, after the outputs 208 and the output 209 are inverted. Furthermore, in the case in which the degradation of the test block 201 progresses afterward, and consequently the output 208 and the output 209 become ‘H’ and ‘L’ respectively, the degradation amount calculating means 214 can calculate an amount of the degradation to be 2/(2×N×M) as a result of the progressive degradation.

On and after, the degradation amount calculating means 214 can calculate a situation of the degradation of the test block by use of the simple configuration by shifting the node to be selected which is at the just rear of the previous node, according to the delay of the rising edge of the output of the frequency divider 204.

Incidentally, the timing when the output 208 becomes ‘L’, and the output 209 becomes ‘H’ at the time of selecting the node is not only t1 but also may be t3 in some cases. But, also in this case, when the rising edge of the output of the frequency divider 204 is delayed from t3 to t4 due to the progressive performance-degradation of the test block 201, the output 208 and output 209 are inverted to ‘H’ and ‘L’ respectively. Then, the degradation amount calculating means 214 can measure an amount of the degradation of the test block 201 by using the same procedure mentioned above.

That is, the degradation amount calculating means 214 can calculate an amount of the degradation of the test block 201 even if the timing when the output 208 and the output 209 are ‘L’ and ‘H’ respectively at the timing of selecting the node is t1 or t4 in FIG. 5.

On and after, the degradation amount calculating means 214 can measure a degree of progression of the degradation by repeating the shifting the node to the just rear of the previous node in the reference block 202 which provides the judgment means 203 with the signal. That is, the degradation diagnosing circuit according to the second exemplary embodiment measures an amount of the delay caused the test block by comparing the outputs of the test block and the reference block without using the counter and many DFFs. As a result, the degradation diagnosing circuit according to the second exemplary embodiment has an effect that it is possible to measure a state of the degradation of the semiconductor integrated circuit with accuracy by use of the simple circuit configuration.

Moreover, the degradation diagnosing circuit according to the second exemplary embodiment can transit from the stand-by mode to the measurement mode successively by the control signal 210 without changing the circuit configurations of the test block 201 and the reference block 202. For this reason, the degradation diagnosing circuit according to the second exemplary embodiment has also an effect that it is possible to reduce the fear that an amount of the degradation is misjudged due to the influence of BTI.

Incidentally, also in the second exemplary embodiment, the judgment means 203 may be equipped with a characteristics adjusting means as a modification like the modification of the first exemplary embodiment. The characteristics adjusting means adjusts an amount of the delay of the input signal so that an amount of the degradation of the test block 201 calculated by the degradation amount calculating means 214, may become null.

The characteristics adjusting means may be arranged, at least, either between the output of the test block 201 and the input of the frequency divider 204, or between the output of the frequency divider 204 and the input of the NAND gate 2021. According to the modification of the second exemplary embodiment, it is possible to find out an amount of the degradation of the test block 201 on the basis of an amount of the delay adjustment which the characteristics adjusting means adjusts in a state in which the degradation amount calculating means 214 does not detect the degradation of the test block 201.

Furthermore, in the modification of the second exemplary embodiment, the judgment means 203 may have a function to output an amount of characteristics adjustment adjusted by the characteristics adjusting means to the outside.

### Third Exemplary Embodiment

According to the configuration of the second exemplary embodiment shown in FIG. 3, the timing of the signals A to C, each of which is delayed by one gate with the inverter group 212 and the rising edge of the output of the frequency divider 204 are compared. That is, resolution for detecting an amount of the delay of the test block 201 is fixed to one gate delay.

In a third exemplary embodiment, a configuration that a signal whose timing is compared with the timing of the output of the frequency divider 204 can be selected freely per each node will be described.

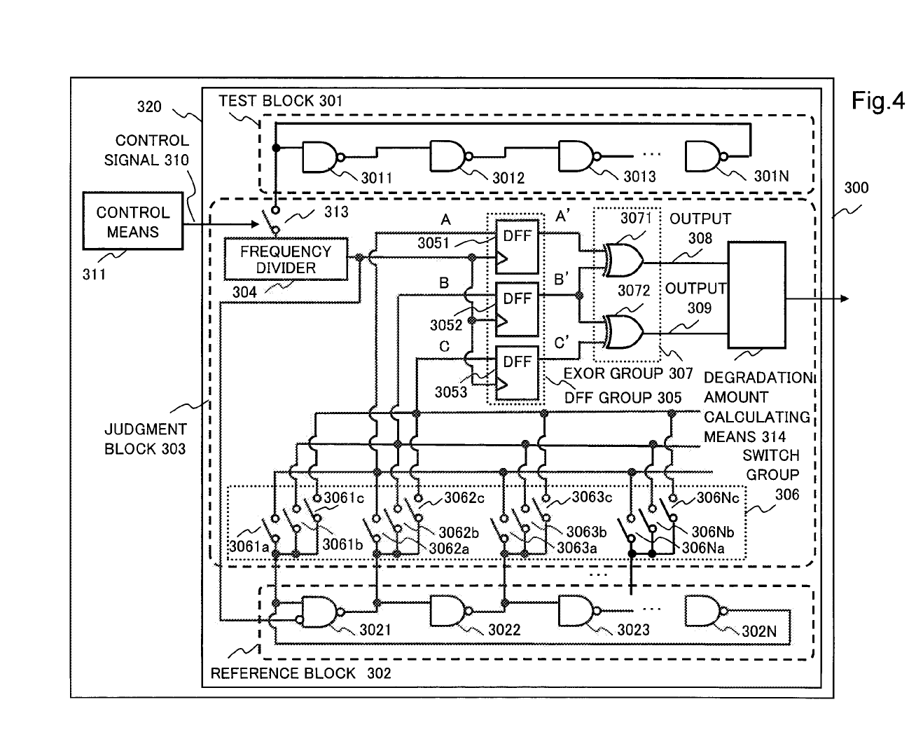

FIG. 4 is a diagram showing a configuration of a degradation diagnosing circuit according to the third exemplary embodiment. A degradation diagnosing circuit 300 shown in FIG. 4 includes a degradation diagnosing block 320 and a control means 311. The degradation diagnosing block 320 includes a test block 301, a reference block 302, and a judgment means 303. Here, a component, a description and the like, which are unnecessary to describe an operation, are omitted appropriately, and it is clear that the configuration shown in FIG. 4 is not limited as only one configuration which can achieve the object of the present invention.

The test block 301 and the reference block 302 shown in FIG. 4 include a logic gate. The test block 301 is a ring oscillator including NAND gates 3011 to 301N, and the reference block 302 is a ring oscillator including NAND gates 3021 to 302N.

The judgment means 303 includes a frequency divider 304, a switch group 306, a DFF group 305, an EXOR group 307 and a degradation amount calculating means 314.

The frequency divider 304 divides a frequency of a signal inputted from any one of nodes of the test block 301, and outputs a signal which includes the divided frequency to the DFF group 305 and the NAND gate 3021 of the reference block 302. Each node of the reference block 302 has three branches, and the switch group 306 connects each of the branches with DFFs 3051 to 3052 of the DFF group 305 respectively.

The DFF group 305 latches outputs of three nodes selected by the switch group 306 at a rising edge of a signal of the frequency divider 304. The EXOR group 307 carries out the exclusive-or operation to two out of three outputs of the DFF group 305. An output 308 and an output 309 are outputs of EXORs 3071 and 3072 respectively, and are inputted to the degradation amount calculating means 314.

The degradation amount calculating means 314 calculates an amount of the degradation of the test block 301 on the basis of the outputs 308 and 309. A specific method used by the degradation amount calculating means 314 calculating an amount of the degradation will be described later.

The switch group 306 includes three switches per the node of the reference block 302. According to FIG. 4, the switch group 306 includes switches 3061a to 3061c, 3062a to 3062c, . . . , and 306Na to 306Nc. When one switch of the switch group 306 is turned on (conducted), an output of the switch is connected with a corresponding DFF of the group 305.

For example, when the switch 3061a is turned on, an output of the NAND gate 302N is inputted to DFF 3051 through a signal line A. Moreover, when the switch 3062b or 3062c is turned on, an output of the NAND gate 3021 is inputted to DFF 3052 or DFF 3053 through a signal line B or a signal line C respectively. An operation of each switch of the switch group 306 is similar also in the case of another node.

According to the third exemplary embodiment, the switch 3061a or the like of the switch group 306 is controlled separately. By this configuration, wirings for the signals A to C can be connected with any nodes of the reference block 302. That is, an amount of the delay between the signals A and the B, and an amount of the delay between the signals B and C can be set in an unit of delay determined by number of the NAND gates. As a result, it is possible to change the resolution for detecting a change of the rising edge of the output of the frequency divider 204 described in FIG. 5 according to the third exemplary embodiment.

According to the configuration described in FIG. 3, the inverter group 212 causes the input signals of DFF 2051 to 2053 the delays different each other by one gate delay. In FIG. 4, for example, by turning on the switch 3061a, the switch 3062b and the switch 3063c, the judgment means 303 can be configured so that the signals whose delays are different each other by one gate delay may be inputted to the DFF group 305.

Furthermore, according to the configuration shown in FIG. 4, for example, by turning on the switch 3061a, the switch 3064b, and the switch 3067c, which are not shown in the figure, apart each other by three stages in terms of the NAND gate signals whose delays are different each other by three gates delay are inputted to the DFF group 305. In this case, a delay between change points of signals A and B, and a delay between change points of signals B and C in FIG. 5 has a length corresponding to a delay of three NAND gates. Accordingly, in the case in which the outputs 308 and 309 are inversed, the test block 301 is caused three gates delay.

At this time, number of the gates through which the signal passes in the test block 301 is 2×N×M, and it is conceivable that the test block 301 is caused increase of the three gates delay due to the degradation. For this reason, the degradation amount calculating means 314 can calculate an amount of the degradation per one gate in the test block 301 to be 3/(2×N×M).

Incidentally, the oscillation operation of the reference block 302 stops by the output of the frequency divider 304 changing from ‘L’ to ‘H’. Since the reference block 302 stopping the oscillation operation, and the DFF group 305 latching the input data provided by the switch group 306 are carried out simultaneously, there is fear that the output signals of the DFF group 205 may be caused disorder. A delay circuit may be arranged between the frequency divider 304 and the reference block 302 so that the DFF group 305 may latch the input signal correctly at a time when the output of the frequency divider 204 changes. Or, a hold circuit may be arranged so that the hold circuit may hold the signal with which the frequency divider 304 provides the reference block 302 until the DFF group 305 latches the input. Or, starting and stopping the oscillation of the reference block 202 may be controlled by using the control signal 310 besides using the output of the frequency divider 304.

As mentioned above, also the degradation diagnosing circuit according to the third exemplary embodiment has an effect that it is possible to measure a state of the degradation of the semiconductor integrated circuit by use of the simple circuit configuration like the degradation diagnosing circuit according to the second exemplary embodiment.

Moreover, according to the third exemplary embodiment, by arranging the switch group 306, it is possible to change a measurement unit (resolution) of an amount of degradation of the test block 301 to be measured. An effect that it is possible to make a variation of the delay per the NAND gate and an error of an amount of the delay due to noise average by making the measurement unit of an amount of the degradation large is obtained.

Incidentally, the degradation diagnosing circuit according to the third exemplary embodiment can transit from the stand-by mode to the measurement mode successively by the control signal 310 without changing the circuit configurations of the test block 301 and the reference block 302 as well as the degradation diagnosing circuit according to the second exemplary embodiment. For this reason, the degradation diagnosing circuit according to the third exemplary embodiment has also an effect that it is possible to reduce the influence of recovery of the degradation due to the influence of BTI.

Here, also in the third exemplary embodiment, the judgment means 303 may be equipped with a characteristics adjusting means as a modification as well as the modification of the first exemplary embodiment. The characteristics adjusting means adjusts an amount of the delay of the input signal so that an amount of the degradation of the test block 301 calculated by the degradation amount calculating means 314 may become null.

The characteristics adjusting means may be arranged, at least, either between the output of the test block 301 and the input of the frequency divider 304, or between the output of the frequency divider 304 and the input of the NAND gate 3021. According to the modification of the third exemplary embodiment, it is possible to find out an amount of the degradation of the test block 301 on the basis of an amount of the delay adjustment which the characteristics adjusting means adjusts in a state in which the degradation amount calculating means 314 does not detect the degradation of the test block 301.

Furthermore, in the modification of the third exemplary embodiment, the judgment means 303 may have a function to output an amount of characteristics adjustment which the characteristics adjusting means adjusts to the outside.

Now, the exemplary embodiment of the present invention has been described with reference to the first to the third exemplary embodiments. However, an embodiment to which the present invention is applicable is not limited to the exemplary embodiment mentioned above. Various changes which a person skilled in the art can understand can be added to the composition and the detailed description of the present invention in the scope of the present invention.

This application is based upon and claims the benefit of priority from Japanese Patent Application No. 2011-182438, filed on Aug. 24, 2011, the disclosure of which is incorporated herein in its entirety by reference.

Here, while the present invention can be described also like the following supplementary notes 1 to 12, an exemplary embodiment of the present invention is not limited to the supplementary notes.

(Supplementary Note 1)

A degradation diagnosing circuit, including:

a test block including a first circuit which is an object of a degradation diagnosis;

a reference block including a second circuit which has a configuration identical with a configuration of the first circuit;

a judgment means for judging whether a component of the test block is degraded or not by comparing first a characteristic of a first signal outputted from the test block, and a second characteristic of a second signal outputted from the reference block, in the case in which a signal indicating a measurement mode is inputted; and

a control means for outputting the signal which indicates the measurement mode to the judgment means.

(Supplementary note 2) The degradation diagnosing circuit according to supplementary note 1, wherein

the first characteristics and the second characteristics are electric characteristics which the first signal and the second signal have respectively and which are changed as a result of the degradation.

(Supplementary note 3) The degradation diagnosing circuit according to supplementary note 2, wherein

each of said first characteristics and said second characteristics includes at least one of a phase, timing of a change, a frequency, an output voltage, an output current, a voltage amplitude, a current amplitude, and an ability to drive a load.

(Supplementary note 4) The degradation diagnosing circuit according to any one of supplementary notes 1 to 3, wherein

the judgment means detects a difference between characteristics of a component of the test block, and characteristics of a component of the reference block.

(Supplementary note 5) The degradation diagnosing circuit according to any one of supplementary notes 1 to 3, including:

a characteristics adjusting means for carrying out a predetermined adjustment to at least one of the first signal and the second signal according to a direction of the judgment means so that the first characteristics and the second characteristics may be equivalent each other, in the case in which the signal indicating the measurement mode is inputted, wherein

the judgment means judges whether the degradation is caused or not on the basis of necessity of the direction.

(Supplementary note 6) The degradation diagnosing circuit according to supplementary note 5, wherein

the judgment means outputs an amount of adjustment necessary to carry out the adjustment as an amount of degradation which indicates a degree of the degradation.

(Supplementary note 7) The degradation diagnosing circuit according to any one of supplementary notes 1 to 6, wherein

either of or both of the first circuit and the second circuit have a cyclic configuration which outputs a signal at a predetermined timing.

(Supplementary note 8) The degradation diagnosing circuit according to any one of supplementary notes 1 to 7, wherein

either of or both of the first circuit and the second circuit have a configuration in which logic gates are connected cyclically.

(Supplementary note 9) The degradation diagnosing circuit according to any one of supplementary notes 1 to 8, wherein

the judgment means compares a delay time of a component of the test block, and a delay time of a component of the reference block.

(Supplementary note 10) The degradation diagnosing circuit according to any one of supplementary notes 1 to 9, wherein

the judgment means includes:

a frequency divider to output a third signal whose frequency is a divided frequency of the first signal;

a latch circuit to latch a fourth signal and a fifth signal which have amounts of delay different each other from the second signal, by use of the third signal, and to output the latched fourth signal and the latch fifth signal;

an EXOR (exclusive-OR) circuit to carry out the exclusive-or operation to the outputs of the latch circuit; and

an degradation amount calculating means for calculating an amount of the degradation on the basis of the output of the EXOR circuit.

(Supplementary note 11) The degradation diagnosing circuit according to supplementary note 10, wherein

the fourth signal and the fifth signal are generated by making the second signal delayed.

(Supplementary note 12) The degradation diagnosing circuit according to supplementary note 10, wherein

the fourth signal and the fifth signal are the second signals outputted from positions corresponding to a preceding stage and a following stage respectively on a predetermined signal transmission path in the reference block.

(Supplementary note 13) The degradation diagnosing circuit according to any one of supplementary notes 1 to 12, wherein

in the case in which the control means does not output the signal which indicates the measurement mode, the test block operates and the reference block stops an operation.

(Supplementary note 14) The degradation diagnosing circuit according to any one of supplementary notes 1 to 13, wherein

the test block and the reference block operate in an operational environment in which stresses different each other are applied to the test block and the reference block respectively.

(Supplementary note 15) A degradation diagnosing method, including:

judging whether a component of a test block which includes a first circuit which is an object of a degradation diagnosis is degraded or not by comparing a first characteristic of a first signal outputted from the test block, and a second characteristic of a second signal outputted from a reference block including a second circuit which has a configuration identical with a configuration of the first circuit, in the case in which a signal indicating a measurement mode is inputted.

### DESCRIPTION OF A CODE

100, 200 and 300 degradation diagnosing circuit
101 degradation diagnosing block
102, 201 and 301 test block
103, 202 and 302 reference block
104, 203 and 303 judgment means
105, 211 and 311 control means
106 degradation diagnosing block
107 characteristics adjusting means
204 and 304 frequency divider
205 and 305 DFF group
206 and 306 switch group
207 and 307 EXOR group
208 and 308 output
209 and 309 output
210 and 310 control signal
213 and 313 switch
214 and 314 degradation amount calculating means
2011 to 201N, 2021 to 202N, and 2121 to 2123 NAND gate
2051 to 2053, and 3051 to 3053 D flip-flop 2061 to 206N switch
3061a to 306Na, 3061b to 306Nb, and 3061c to 306Nc switch
2071, 2072, 3071 and 3072 EXOR gate

1. A degradation diagnosing circuit, comprising:
a test block including a first circuit which is an object of a degradation diagnosis;
a reference block including a second circuit which has a configuration identical with a configuration of the first circuit;
a judgment unit that judges whether a component of the test block is degraded or not by comparing a first characteristic of a first signal outputted from the test block, and a second characteristic of a second signal outputted from the reference block, in the case in which a signal indicating a measurement mode is inputted; and
a control unit that outputs the signal which indicates the measurement mode to the judgment unit.

2. The degradation diagnosing circuit according to claim 1, wherein
the first characteristic and the second characteristic are electric characteristics which the first signal and the second signal have respectively and which are changed as a result of the degradation.

3. The degradation diagnosing circuit according to claim 1, comprising:
a characteristics adjusting unit that carries out a predetermined adjustment to at least one of the first signal and the second signal according to a direction of the judgment unit so that the first characteristic and the second characteristic may be identical each other, in the case in which the signal indicating the measurement mode is inputted, wherein
the judgment unit judges whether the degradation is caused or not on the basis of necessity of the direction.

4. The degradation diagnosing circuit according to claim 3, wherein
the judgment unit outputs an amount of adjustment necessary to carry out the adjustment as an amount of degradation which indicates a degree of the degradation.

5. The degradation diagnosing circuit according to claim 1, wherein
the judgment unit comprises:
a frequency divider to output a third signal whose frequency is a divided frequency of the first signal;
a latch circuit to latch a fourth signal and a fifth signal which have amounts of delay different each other from the second signal by use of the third signal and to output the latched fourth signal and the latch fifth signal;
an EXOR (exclusive-OR) circuit to carry out the exclusive-or operation to the outputs of the latch circuit; and
an degradation amount calculating unit that calculates an amount of the degradation on the basis of the output of the EXOR circuit.

6. The degradation diagnosing circuit according to claim 5, wherein
the fourth signal and the fifth signal are generated by making the second signal delayed.

7. The degradation diagnosing circuit according to claim 5, wherein
the fourth signal and the fifth signal are the second signals outputted from positions corresponding to a preceding stage and a following stage respectively on a predetermined signal transmission path in the reference block.

8. The degradation diagnosing circuit according to claim 1, wherein
in the case in which the control unit does not output the signal which indicates the measurement mode, the test block operates and the reference block stops an operation.

9. The degradation diagnosing circuit according to claim 1, wherein
the test block and the reference block operate in an operational environment in which stresses different each other are applied to the test block and the reference block respectively.

10. A degradation diagnosing method, comprising
judging whether a component of a test block which includes a first circuit which is an object of a degradation diagnosis is degraded or not by comparing first characteristic of a first signal outputted from the test block, and second characteristic of a second signal outputted from a reference block including a second circuit which has a configuration identical with a configuration of the first circuit, in the case in which a signal indicating a measurement mode is inputted.

11. A semiconductor integrated circuit device comprising the degradation diagnosing circuit according to claim 1.

12. A degradation diagnosing circuit, comprising:
a test block including a first circuit which is an object of a degradation diagnosis;
a reference block including a second circuit which has a configuration identical with a configuration of the first circuit;
a judgment means for judging whether a component of the test block is degraded or not by comparing first characteristic of a first signal outputted from the test block, and second characteristic of a second signal outputted from the reference block, in the case in which a signal indicating a measurement mode is inputted; and
a control means for outputting the signal which indicates the measurement mode to the judgment means.
